(19) United States
(12) Patent Application Publication
(10) Pub. No.: US 2025/0078916 A1
(43) Pub. Date: Mar. 6, 2025

(54) TECHNIQUES FOR IDENTIFYING SELF-TIME AND BREAKPOINTS FOR MEMORY

(71) Applicant: Synopsys, Inc., Sunnyvale, CA (US)

(72) Inventors: Prasanna NALAWAR, Bengalurui (IN); Ayushi KUMARI, Bihar (IN); Vineet Kumar SACHAN, Bengalore (IN)

(21) Appl. No.: 18/238,859

(22) Filed: Aug. 28, 2023

(51) Int. Cl. G11C 11/419; G06F 30/3323; G11C 11/412

(52) U.S. Cl. CPC G11C 11/419; G06F 30/3323; G11C 11/412

(57) ABSTRACT

Certain aspects of the present disclosure include a method for memory processing. The method generally includes determining, via one or more processors and for each of different quantities of columns per section of a memory, a read signal indicating a change in a bitline signal during a read window based on at least one calculated slope of the bitline signal during the read window, where the read signal being determined for each of the different quantities of the columns per section of the memory yields a plurality of read signals; determining a difference between at least two of the plurality of read signals, identifying breakpoints within the memory based on the difference between the at least two of the plurality of read signals. The method also includes generating a representation of the memory based on the breakpoints.

### TECHNICAL FIELD

The present disclosure generally relates to memory processing, and more particularly, to a memory compiler identifying breakpoints for a memory.

### BACKGROUND

Memory plays an important role in electronic devices such as smartphones and computers. A memory compiler may be used to efficiently integrate memory into electronic devices. Memory compilers simplify the process of designing and improving memory structures. A memory compiler may be used to automate the generation of memory arrays based on predefined specifications. Based on user specifications, a memory compiler may provide memory architectures that can be implemented on a chip.

### SUMMARY

The following presents a simplified summary of one or more aspects of the present disclosure, in order to provide a basic understanding of such aspects. This summary is not an extensive overview of all contemplated features of the disclosure, and is intended neither to identify key or critical elements of all aspects of the disclosure nor to delineate the scope of any or all aspects of the disclosure. Its sole purpose is to present some concepts of one or more aspects of the disclosure in a simplified form as a prelude to the more detailed description that is presented later.

Certain aspects of the present disclosure include a method for memory processing. The method generally includes determining, via one or more processors and for each of different quantities of columns per section of a memory, a read signal indicating a change in a bitline signal during a read window based on at least one calculated slope of the bitline signal during the read window, where the read signal being determined for each of the different quantities of the columns per section of the memory yields a plurality of read signals; determining a difference between at least two of the plurality of read signals, identifying breakpoints within the memory based on the difference between the at least two of the plurality of read signals. The method also includes generating a representation of the memory based on the breakpoints.

Certain aspects of the present disclosure include an apparatus for memory processing. The apparatus generally includes a storage device. The apparatus also includes one or more processors coupled to the storage device, the one or more processing being configured to: determine, for each of different quantities of columns per section of a memory, a read signal indicating a change in a bitline signal during a read window based on at least one calculated slope of the bitline signal during the read window, where the read signal being determined for each of the different quantities of the columns per section of the memory yields a plurality of read signals; determine a difference between at least two of the plurality of read signals; identify breakpoints within the memory based on the difference between the at least two of the plurality of read signals; and generate the representation of the memory based on the breakpoints.

Certain aspects of the present disclosure include a non-transitory computer-readable medium having instructions stored thereon, that when executed by one or more processors, cause the one or more processors to: determine, for each of different quantities of columns per section of a memory, a read signal indicating a change in a bitline signal during a read window based on at least one calculated slope of the bitline signal during the read window, wherein the read signal being determined for each of the different quantities of the columns per section of the memory yields a plurality of read signals; determine a difference between at least two of the plurality of read signals; identify breakpoints within the memory based on the difference between the at least two of the plurality of read signals; and generate the representation of the memory based on the breakpoints.

### BRIEF DESCRIPTION OF THE DRAWINGS

The disclosure will be understood more fully from the detailed description given below and from the accompanying figures of embodiments of the disclosure. The figures are used to provide knowledge and understanding of embodiments of the disclosure and do not limit the scope of the disclosure to these specific embodiments. Furthermore, the figures are not necessarily drawn to scale.

FIG. 1 illustrates an example memory cell of a static random access memory (SRAM).

FIG. 2 illustrates a memory system including memory arrays with multiple rows and columns.

FIG. 3 is a flow diagram illustrating example operations for memory tuning and breakpoint identification, in accordance with certain aspects of the present disclosure.

FIG. 4 is a graph illustrating a bitline (BL) voltage, a complementary BL (BLB) voltage, a wordline (WL) voltage, and a complementary sense enable (SAEB) voltage, in accordance with certain aspects of the present disclosure.

FIG. 5A is a table illustrating calculated read signals for different columns per section of memory, in accordance with certain aspects of the present disclosure.

FIG. 5B is a table illustrating calculated read signals for different columns per section of memory after RC mismatch reduction, in accordance with certain aspects of the present disclosure.

FIG. 5C is a table illustrating calculated and simulated wordline slopes for different columns per section of memory, in accordance with certain aspects of the present disclosure.

FIG. 5D is a table illustrating calculated and simulated effective read windows for different columns per section of memory, in accordance with certain aspects of the present disclosure.

FIG. 6 is a flow diagram illustrating example operations for memory processing, in accordance with certain aspects of the present disclosure.

FIG. 7 illustrates an example set of processes used during the design, verification, and fabrication of an article of manufacture.

FIG. 8 illustrates an example computer system having a compiler, in accordance with certain aspects of the present disclosure.

### DETAILED DESCRIPTION

Certain aspects of the present disclosure are directed towards a memory compiler used to generate a representation of memory. The memory may include an array of memory cells, such as static random access memory (SRAM) memory cells, as described in more detail herein. The memory compiler may calculate read signals for different numbers of columns per section of memory. Based on the read signals, the compiler may identify breakpoints for the memory. The compiler may perform resistance and capacitance matching of different global lines of the memory to reduce the number of breakpoints. The compiler may use the breakpoints to tune the memory (e.g., tune read and write margins for the memory). Performing the tuning of the memory may involve various simulations for different sections of the memory based on the breakpoints. Thus, reducing the number of breakpoints results in a reduction in the simulation overhead of the compiler when tuning the memory.

Advantages of the present disclosure include, but are not limited to, increased efficiency associated with generating a memory representation by a memory compiler. Thus, certain aspects provide quicker memory design closure (e.g., memory characterization and tuning), reduced machine resources associated with the memory compiler, and improved memory designs (e.g., by allowing for a more effective tuning of the read and write margins of the memory).

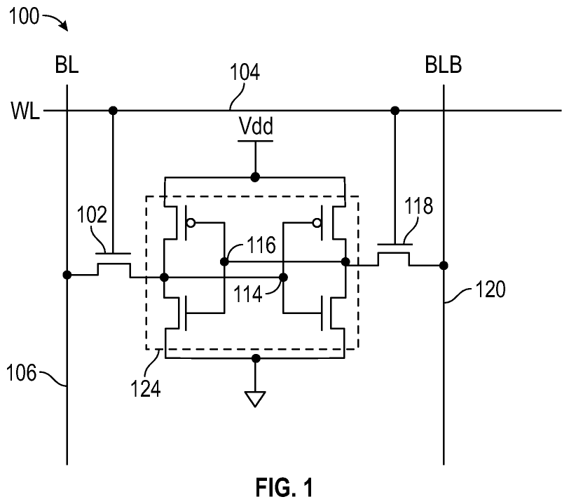

FIG. 1 illustrates an example memory cell 100 of a SRAM. As shown, the memory cell 100 may include a cross-coupled invertor pair 124 having an output 114 and an output 116. As shown, the cross-coupled invertor pair output 114 is selectively coupled to a bit-line (BL) 106 via a pass-gate transistor 102, and the cross-coupled invertor pair output 116 is selectively coupled to a complementary bit-line (BLB) 120 via a pass-gate transistor 118. The BL 106 and BLB 120 are configured to provide complementary digital signals to be written (e.g., stored) in the cross-coupled invertor pair 124. The BL and BLB may be used to store a bit in the memory cell 100. The gates of pass-gate transistors 102, 118 may be coupled to a word-line (WL) 104, as shown. For example, a digital signal to be written may be provided to the BL (and a complement of the digital signal is provided to the BLB). The pass-gate transistors 102, 118—which are implemented here as n-type field-effect transistors (NFETs)—are then turned on by providing a logic high signal to WL 104, resulting in the digital signal being stored in the cross-coupled invertor pair 124.

The size of any memory is represented by the multiplication of rows and columns, where rows represent the number of WLs and columns represent the number of BLs. The access time and cycle time in embedded memories vary across the rows and columns. The change in rows and columns of memory may be tracked to automatically adjust the self-time associated with the memory. A circuit for adjusting the self-time may be referred to as a self-time circuit, which sometimes includes resistance and capacitance tracking, logical delays, and pull-down circuits. Self-time generally refers to identifying a delay associated with performing certain operations, such as a read or write operation, for the memory. For example, a self-time signal (e.g., having a certain self-time pulse width) may be generated to control the read operations of the memory based on the calculated self-time parameters. It is important to reduce such self-time delays to provide faster operations for the memory. The number of simulations increases for every major activity of memory development, like self-time tuning, margin closure, and characterization.

Creating an embedded memory compiler is a task that involves both design (self-time tuning) and computing resources (simulations). With the addition of column multiplexing, multi-bank memory, and many other options for memory compilers to implement, a memory compiler may have to run many simulations to improve (e.g., optimize) the self-time loop.

Achieving self-time tuning for the compiler range involves performing many simulations and precise design tuning like resistance and capacitance (RC) tuning or delay tuning. Self-time tuning parameters (e.g., a read signal, also referred to herein as a minimum read signal) may be determined in certain aspects of the present disclosure. Deviation of the self-time tuning parameters across rows and columns of the memory may be observed to determine design breakpoints for the compiler, as described in more detail herein. For example, a number of design breakpoints may be reduced by reducing a mismatch between resistance and capacitance values associated with different signals involved in self-time tuning, as described in more detail herein.

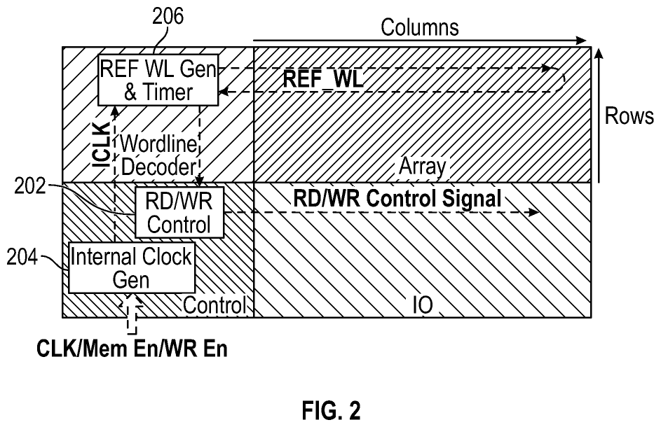

FIG. 2 illustrates a memory system 200 including memory arrays with multiple rows and columns. Each row may include a row decoder and WL buffer. The columns may be coupled to a column multiplexer (labeled “column MUX”) controlled by a local control buffer. The columns may be coupled to sense amplifiers (labeled “Sense Amp”) and write drivers. During a read cycle, a sense amplifier may be used to sense (e.g., read) a digital signal on a BL. The sense amplifiers may be enabled using an enable signal (e.g., a complementary enable signal labeled “ENB”). The memory system may include an internal clock (CLK) generation circuit 204 for generating CLK signals for the memory. An internal CLK from the internal CLK generation circuit 204 may be provided to a reference (REF) WL generator and timer 206, which may generate a reference WL signal (e.g., REF_WL) that may be used to operate the memory system. The CLK generation circuit 204 may receive memory enable (Mem_En) and write enable (WR_En) signals. The memory system may also include a read/write control circuit 202 for controlling read and write operations for the memory system (e.g., using read (RD) and write (WR) control signals, as shown). In some cases, the control circuit 202 may generate a precharge (PRCH) signal, which may be used to precharge various nodes of the memory system. The memory system may also include a global control buffer and various global input/output (IO) interfaces for the columns, as shown.

A user may select various features to be implemented for the memory system 100. For example, as shown in FIG. 2, the memory system 100 may include rows for implementing various features directed towards, for example, redundancy control, write assist control, and power gating (GPG). The memory system 100 may be implemented without such features. The user changing various features of the memory system impacts the tuning parameters of the memory system, which may be reanalyzed by the compiler using simulations. Certain aspects of the present disclosure are directed towards techniques for efficiently determining self-time tuning parameters, reducing the number of simulations to be performed by the compiler.

In some aspects, a large memory array may be divided into different sections based on identified breakpoints. For instance, assume a memory with 256 rows and 256 columns. The memory's access and cycle times change across the columns and rows. So to efficiently tune the memory array, the array may be divided into multiple sections. For instance, the memory array may be divided into multiple sections having 32 rows and 32 columns. Each of the sections may be tuned separately. The point of division of the memory array into respective sections may be referred to as a breakpoint. Reducing the number of breakpoints (e.g., memory array sections) results in a reduced number of simulations that would have to be performed by the compiler to tune the memory array. In some aspects of the present disclosure, the memory compiler may determine self-timing parameters and provide breakpoints to increase tuning efficiency.

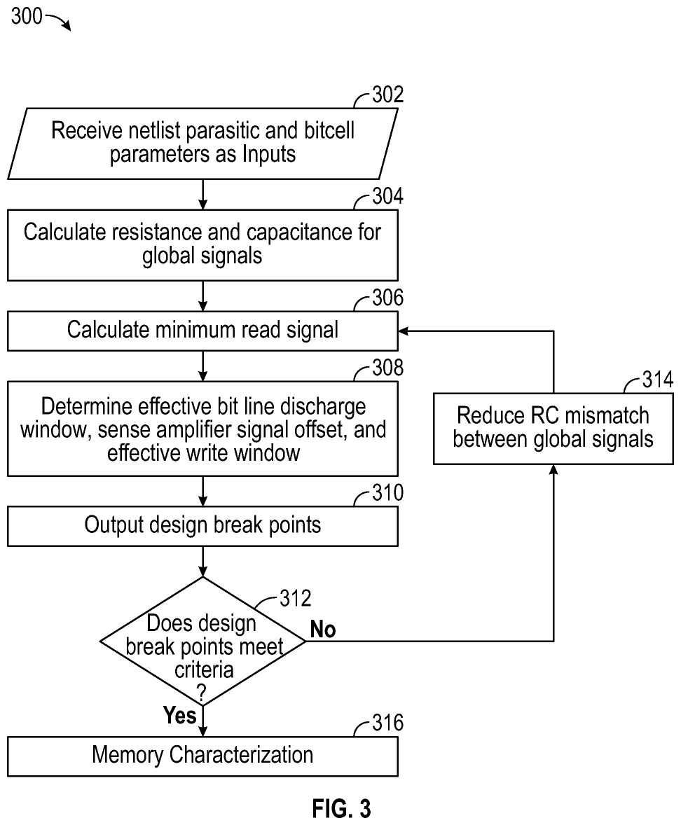

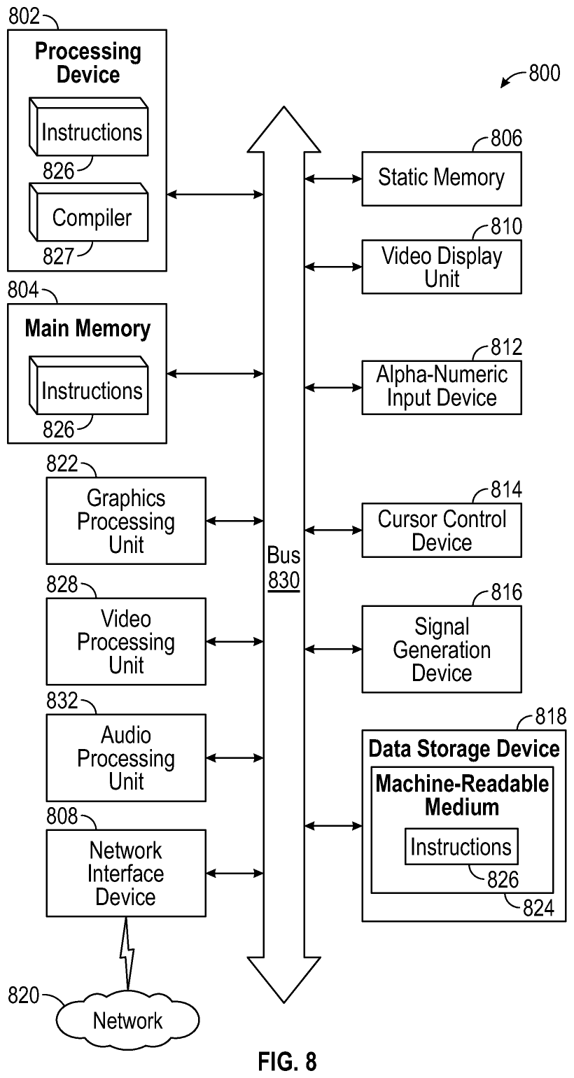

FIG. 3 is a flow diagram illustrating example operations 300 for memory tuning and breakpoint identification, in accordance with certain aspects of the present disclosure. The operations 300 may be performed, for example, by a memory compiler, such as the memory compiler 827 of FIG. 8. At block 302, the compiler may receive netlist parasitic and bitcell parameters, based on which resistance and capacitance (RC) values for global signals of memory may be calculated at block 304. The global signals may include, for example, a signal (e.g., voltage) at a WL of the memory (e.g., WL 104 of FIG. 1), a signal at a read WL (RWL) of the memory, or a signal at a sense amplifier enable (SAE) line of the memory. For each global signal of the memory, a read signal (e.g., a minimum read signal) may be calculated (e.g., based on calculated delay and slope values) at block 306. The minimum read signal may be calculated using the expression:

$$\frac{\{ ( Irea d / {( V d d - V t h )}^{2} ) * {( ( V d d * Vwl\_target ) - V t h )}^{2} ) \}}{\{ ( {C}_{b t} @ array * Rows ) + C\_bt @ io \}} * E W$$

where Iread is the bitcell read current (e.g., the current consumption of a bitcell during read operations), Vdd is the supply voltage for the bit cell, Vth is the device threshold voltage (e.g., threshold voltage associated with pass-gate transistors 102, 118), Cht@array is the bitline capacitance for the array memory cell, Cbt@io is the bitline capacitance in IO (e.g., the capacitance associated with the IO interface for the bitline), Rows is the total number of wordlines of the memory, Vwl_target is the wordline voltage level target (e.g., a logic high voltage at the WL), and EW is the effective read window. The effective read window may refer to a duration of time from when a WL signal reaches 80% of a logic high voltage until a sense enable signal reaches 50% of the logic high voltage, as described in more detail herein. Thus, the minimum read signal may correspond to a signal generated at a BLB (or BL) (e.g., a change in voltage at the BLB) during the effective read window.

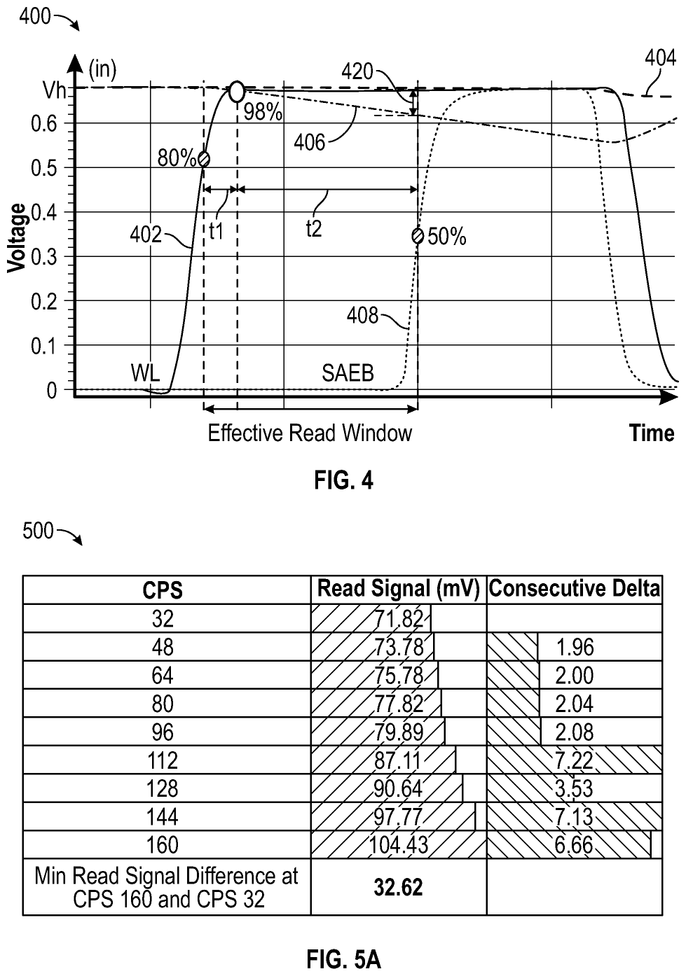

FIG. 4 is a graph 400 illustrating a BL signal 404, a complementary BL (BLB) signal 406, a WL signal 402, and a sense enable (SAEB) signal 408, in accordance with certain aspects of the present disclosure. As shown, the WL signal 402 (e.g., WL voltage) may transition from logic low to logic high. As described with respect to FIG. 1, the WL signal 402 transitioning to logic high results in pass-gate transistors being turned on. As a result, the BLB signal 406 may decrease (e.g., depending on the logic state stored in the memory cell). A certain minimum voltage difference 420 should be reached between the BL signal 404 and BLB signal 406 at the time the sense amplifier is enabled (e.g., at the time when the SAEB signal 408 reaches 50% of the logic high voltage labeled “Vh” in FIG. 4). The calculated read signal described herein may correspond to the minimum voltage difference 420. The read signal is calculated based on a product of the duration of the effective read window and a slope of the BLB signal 406 during the effective read window. The slope may be the rate of change of the signal at the BLB in millivolts per picosecond.

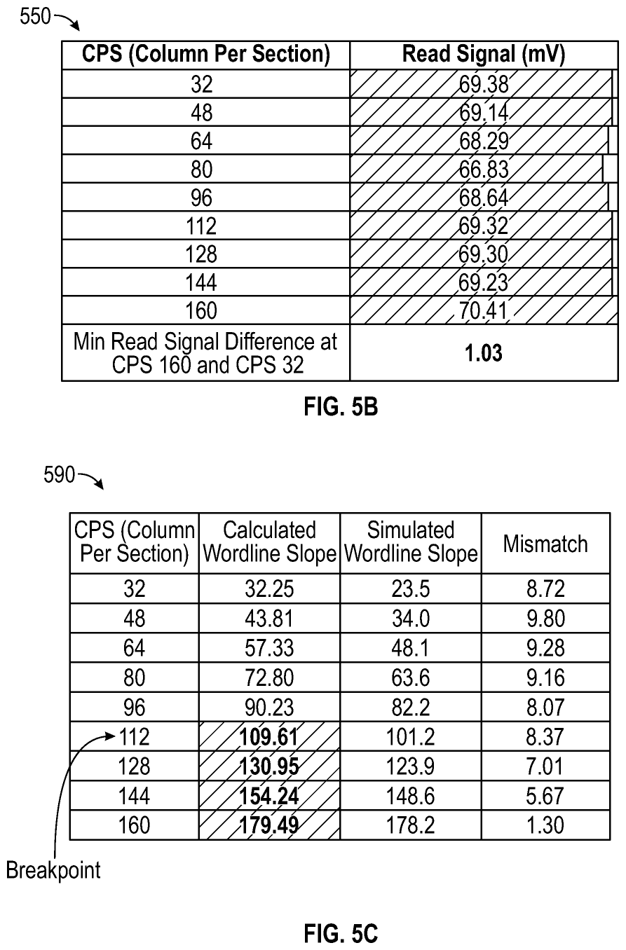

In some cases, the effective read window may be split into two sections, including a first time duration (labeled “t1”) from when the WL signal 402 reaches 80% of the logic high voltage till the WL signal 402 reaches 98% of the logic high voltage, and a second time duration (labeled “t2”) from when WL signal 402 reaches 98% of the logic high voltage until the SAEB signal 408 reaches 50% of the logic high voltage, as shown. In certain aspects of the present disclosure, the read signal may be calculated based on a calculated slope of the BLB signal 406 during the first time duration and a calculated slope of the BLB signal 406 during the second time duration, providing a more accurate read signal calculation. The read signal may be calculated for different quantities of columns per section (CPS) of the memory array. In other words, different sections of memory may be considered with different numbers of columns. For example, the read signal may be calculated for 32 columns per section of memory, 48 columns per section of memory, and so on, as described in more detail herein. In calculating the slope of the read signal (BLB signal 406), the entire capacitance from a top memory bank row to the sense amplifier internal nets may be considered. The read signal may be calculated using the expression provided herein and used to calculate deviation across different CPS of the memory array to determine design breakpoints. For instance, referring back to FIG. 3, based on the read signals calculated at block 306, design breakpoints may be determined at block 310, as described in more detail with respect to FIG. 5. In some aspects, at block 308, an effective bitline discharge window, sense amplifier signal offset, and effective write window (e.g., together forming an effective read window) may be determined at block 308.

FIG. 5A is a table 500 illustrating calculated read signals for different CPS of memory, in accordance with certain aspects of the present disclosure. The read signal may increase as the number of columns per section increases. As shown, for a CPS of 32, a read signal may be calculated as 71.82, for a CPS of 48, a read signal may be calculated as 73.78, and so on. The table 500 shows consecutive delta values generated based on the calculated read signals. The consecutive delta values correspond to the difference between two consecutive read signals. For example, a difference between the read signal of 73.78 for CPS of 32 and the read signal of 71.82 for CPS of 48 provides a delta value of 1.96, as shown. Similarly, a difference between the read signal of 73.78 for CPS of 48 and the read signal of 75.78 for CPS of 64 provides a delta value of 2.00, as shown. The breakpoints for the memory array may be determined based on the consecutive delta values. For example, if a delta value is greater than a certain threshold (e.g., 3 mV), a breakpoint may be set for the corresponding column. In the example shown in table 500, a breakpoint may be set after column 96 since the delta value for CPS of 122 is 7.22 (e.g., greater than the threshold of 3 mV, as an example).

Referring back to FIG. 3, once breakpoints are determined, the compiler may determine, at block 312, whether the breakpoints meet a certain criteria (e.g., if the number of the breakpoints has been reduced to a certain threshold). If not, at block 314, the compiler may reduce the memory's RC mismatch between the global signals (e.g., the mismatch between WL and SAEB line). After reducing the RC mismatch, the compiler may recalculate the read signals for the different CPS, as described herein, and output new breakpoints.

FIG. 5B is a table 550 illustrating calculated read signals for different CPS of memory after RC mismatch reduction, in accordance with certain aspects of the present disclosure. For example, as shown in FIG. 5B, the difference between the read signals for the different CPS is reduced. In this example, the difference between the read signal for CPS 160 and the read signal for CPS 32 is reduced to 1.3 (e.g., as compared to table 500 where the difference was 32.62). Thus, no breakpoints may be necessary in this case by reducing the mismatch. Reducing the number of breakpoints reduces the simulation overhead associated with processing a memory array by the compiler, as described herein.

FIG. 5C is a table 590 illustrating calculated and simulated wordline slopes for different CPS of memory. FIG. 5D is a table 592 illustrating calculated and simulated effective read windows for different CPS of memory. As shown, simulation and calculated values are co-relating for wordline signal slope and effective read window. As shown, a rebuff point (e.g., breakpoint) may be identified for the design using the calculated values (e.g., formula) without performing any simulations using resistance and capacitance values associated with signals for the design.

Referring back to FIG. 3, once the breakpoints are determined and outputted at block 310, the compiler may perform characterization for the memory at block 316. For example, the compiler may tune the memory based on the breakpoints. The compiler may separately analyze the different sections of the memory associated with the breakpoints to tune the memory (e.g., tune read and write margins) and generate a memory representation.

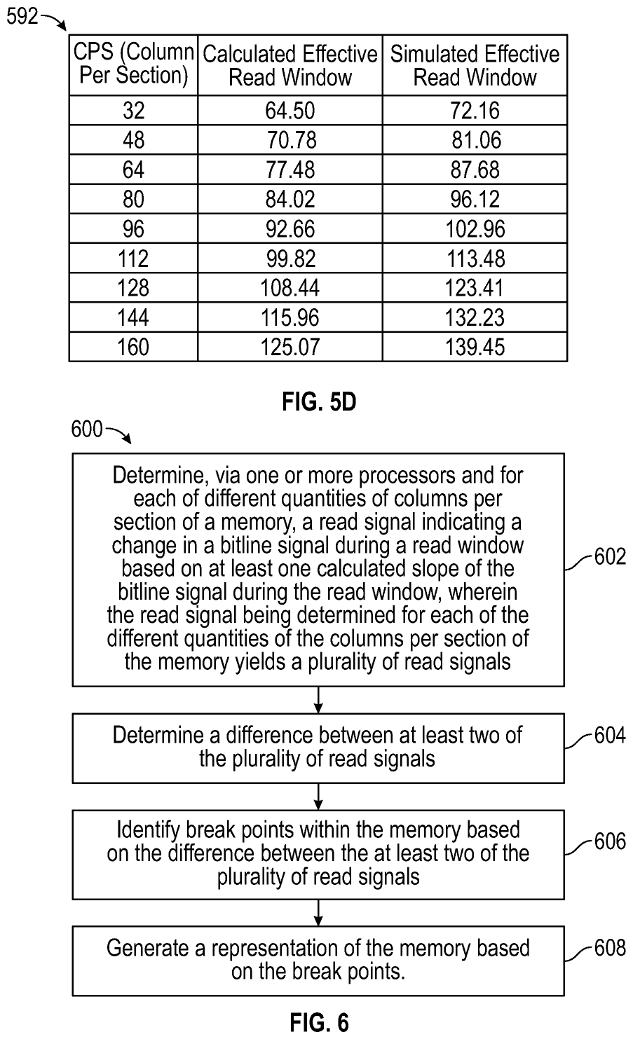

FIG. 6 is a flow diagram illustrating example operations 600 for memory processing, in accordance with certain aspects of the present disclosure. The operations 600 may be performed, for example, by a compiler, such as the memory compiler 827 of FIG. 8.

At block 602, the compiler may determine, for each of different quantities of columns per section of the memory (e.g., for the different CPS shown in FIG. 5), a read signal (e.g., a minimum read signal) indicating a change in a bitline signal (e.g., signal 406 at a complementary bitline of the memory) during a read window (e.g., effective read window shown in FIG. 4) based on at least one calculated slope of the bitline signal during the read window. The change in the bitline signal may include a difference between a signal at a bitline of the memory and a signal at a complementary bitline of the memory (e.g., difference 420 between BL signal 404 and BLB signal 406 as shown in FIG. 4). The read signal being determined for each of the different quantities of the columns per section of the memory yields a plurality of read signals.

In some aspects, the read window may include a time duration from a rising edge of a wordline signal (e.g., WL signal 402) of the memory until a rising edge of a sense amplifier enable signal (e.g., SAEB signal 408) of the memory. The rising edge of the wordline signal may include a time at which the wordline signal reaches 80% of a logic high voltage, and the rising edge of the sense amplifier enable may include a time at which the sense amplifier enable signal reaches 50% of the logic high voltage.

In some aspects, the at least one calculated slope may include a first calculated slope of the bitline signal for a first portion (e.g., time duration t1 shown in FIG. 4) of the read window and a second calculated slope of the bitline signal for a second portion (e.g., time duration t2 shown in FIG. 4) of the read window. The first portion of the read window may include a time at which a wordline signal of the memory reaches 80% of a logic high voltage until a time at which the wordline signal reaches 98% of the logic high voltage. The second portion of the read window may include the time at which the wordline signal reaches 98% of the logic high voltage until a time at which a sense amplifier enable signal of the memory reaches 50% of the logic high voltage.

At block 604, the compiler may determine a difference between at least two of the plurality of read signals. For example, the at least two of the plurality of read signals may be for two consecutive quantities of the columns per section of the memory (e.g., for CPS 32 and 48, as described with respect to FIG. 5).

At block 606, the compiler identifies breakpoints within the memory based on the difference between the at least two of the plurality of read signals, and at block 608, generates the representation of the memory based on the breakpoints. For example, generating the representation of the memory based on the breakpoints may include separately tuning different sections of the memory based on the breakpoints within the memory. In some aspects, the compiler may reduce a resistance or capacitance mismatch between at least two lines (e.g., a wordline and a sense amplifier enable line) of the memory prior to determining the plurality of read signals

In some aspects, the at least one calculated slope may be calculated based on at least one of a read current (e.g., Iread) associated with a bitcell of the memory, a supply voltage (e.g., Vdd) for the memory, a threshold voltage (e.g., Vth) of the memory, a bitline capacitance (e.g., Cbt@array) associated with the memory, a capacitance (e.g., Cbt@io) at a bitline input and output (I/O) interface for the memory, a quantity of wordlines (e.g., Rows) of the memory, or a wordline voltage level target (e.g., Vwl_target) of the memory.

The compiler described herein may determine memory self-time breakpoints using pre-simulation techniques. For example, resistance, capacitance, or bitcell parameters such as read current and write time may be used to calculate read signals to determine the breakpoints, as described. Certain aspects of the present disclosure reduce the simulation overhead of the compiler and provide design features early in the development phase, reducing repetitions associated with self-time loop closure and improving productivity.

Certain aspects provide quicker design closure and productivity improvements. The techniques described herein are used to identify design breakpoints and resistance and capacitance specifications before a design tuning cycle using extracted netlists, reducing iterations for self-time closure. For example, certain aspects improve productivity by reducing a number of breakpoints compared to conventional compilers. Machine resource usage may be reduced by reducing the number of design breakpoints. Reducing the number of breakpoints allows for tuning of the read and write margins of the memory more efficiently. Reduction in design breakpoints also reduces the trend mismatch across rows and columns. A re-buffer breakpoint may be identified based on RC specifications, in some aspects.

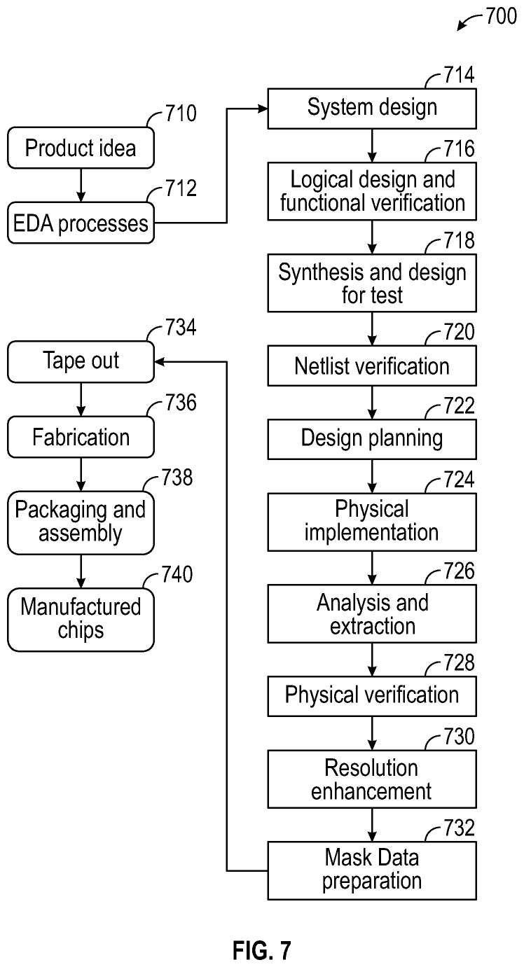

FIG. 7 illustrates an example set of processes 700 used during the design, verification, and fabrication of an article of manufacture such as an integrated circuit to transform and verify design data and instructions that represent the integrated circuit. Each of these processes can be structured and enabled as multiple modules or operations. The term ‘EDA’ signifies the term ‘Electronic Design Automation.’ These processes start with the creation of a product idea 710 with information supplied by a designer, information which is transformed to create an article of manufacture that uses a set of EDA processes 712. When the design is finalized, the design is taped-out 734, which is when artwork (e.g., geometric patterns) for the integrated circuit is sent to a fabrication facility to manufacture the mask set, which is then used to manufacture the integrated circuit. After tape-out, a semiconductor die is fabricated 736 and packaging and assembly processes 738 are performed to produce the finished integrated circuit 740.

Specifications for a circuit or electronic structure may range from low-level transistor material layouts to high-level description languages. A high-level representation may be used to design circuits and systems, using a hardware description language (‘HDL’) such as VHDL, Verilog, System Verilog, SystemC, MyHDL or OpenVera. The HDL description can be transformed to a logic-level register transfer level (‘RTL’) description, a gate-level description, a layout-level description, or a mask-level description. Each lower representation level that is a more detailed description adds more useful detail into the design description, for example, more details for the modules that include the description. The lower levels of representation that are more detailed descriptions can be generated by a computer, derived from a design library, or created by another design automation process. An example of a specification language at a lower level of representation language for specifying more detailed descriptions is SPICE, which is used for detailed descriptions of circuits with many analog components. Descriptions at each level of representation are enabled for use by the corresponding tools of that layer (e.g., a formal verification tool). A design process may use a sequence depicted in FIG. 7. The processes described by be enabled by EDA products (or tools).

During system design 714, functionality of an integrated circuit to be manufactured is specified. The design may be optimized for desired characteristics such as power consumption, performance, area (physical and/or lines of code), and reduction of costs, etc. Partitioning of the design into different types of modules or components can occur at this stage.

During logic design and functional verification 716, modules or components in the circuit are specified in one or more description languages and the specification is checked for functional accuracy. For example, the components of the circuit may be verified to generate outputs that match the requirements of the specification of the circuit or system being designed. Functional verification may use simulators and other programs such as testbench generators, static HDL checkers, and formal verifiers. In some embodiments, special systems of components referred to as ‘emulators’ or ‘prototyping systems’ are used to speed up the functional verification.

During synthesis and design for test 718, HDL code is transformed to a netlist. In some embodiments, a netlist may be a graph structure where edges of the graph structure represent components of a circuit and where the nodes of the graph structure represent how the components are interconnected. Both the HDL code and the netlist are hierarchical articles of manufacture that can be used by an EDA product to verify that the integrated circuit, when manufactured, performs according to the specified design. The netlist can be optimized for a target semiconductor manufacturing technology. Additionally, the finished integrated circuit may be tested to verify that the integrated circuit satisfies the requirements of the specification.

During netlist verification 720, the netlist is checked for compliance with timing constraints and for correspondence with the HDL code. During design planning 722, an overall floor plan for the integrated circuit is constructed and analyzed for timing and top-level routing.

During layout or physical implementation 724, physical placement (positioning of circuit components such as transistors or capacitors) and routing (connection of the circuit components by multiple conductors) occurs, and the selection of cells from a library to enable specific logic functions can be performed. As used herein, the term ‘cell’ may specify a set of transistors, other components, and interconnections that provides a Boolean logic function (e.g., AND, OR, NOT, XOR) or a storage function (such as a flipflop or latch). As used herein, a circuit ‘block’ may refer to two or more cells. Both a cell and a circuit block can be referred to as a module or component and are enabled as both physical structures and in simulations. Parameters are specified for selected cells (based on ‘standard cells’) such as size and made accessible in a database for use by EDA products.

During analysis and extraction 726, the circuit function is verified at the layout level, which permits refinement of the layout design. During physical verification 728, the layout design is checked to ensure that manufacturing constraints are correct, such as DRC constraints, electrical constraints, lithographic constraints, and that circuitry function matches the HDL design specification. During resolution enhancement 730, the geometry of the layout is transformed to improve how the circuit design is manufactured.

During tape-out, data is created to be used (after lithographic enhancements are applied if appropriate) for production of lithography masks. During mask data preparation 732, the ‘tape-out’ data is used to produce lithography masks that are used to produce finished integrated circuits.

A storage subsystem of a computer system (such as computer system 800 of FIG. 8) may be used to store the programs and data structures that are used by some or all of the EDA products described herein, and products used for development of cells for the library and for physical and logical design that use the library.

FIG. 8 illustrates an example machine of a computer system 800 within which a set of instructions, for causing the machine to perform any one or more of the methodologies discussed herein, may be executed. In alternative implementations, the machine may be connected (e.g., networked) to other machines in a LAN, an intranet, an extranet, and/or the Internet. The machine may operate in the capacity of a server or a client machine in client-server network environment, as a peer machine in a peer-to-peer (or distributed) network environment, or as a server or a client machine in a cloud computing infrastructure or environment.

The machine may be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 800 includes a processing device 802, a main memory 804 (e.g., read-only memory (ROM), flash memory, dynamic random access memory (DRAM) such as synchronous DRAM (SDRAM), a static memory 806 (e.g., flash memory, static random access memory (SRAM), etc.), and a data storage device 818, which communicate with each other via a bus 830.

Processing device 802 represents one or more processors such as a microprocessor, a central processing unit, or the like. More particularly, the processing device may be complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 802 may also be one or more special-purpose processing devices such as an application specific integrated circuit (ASIC), a field programmable gate array (FPGA), a digital signal processor (DSP), network processor, or the like. The processing device 802 may be configured to execute instructions 826 for performing the operations and steps described herein.

The computer system 800 may further include a network interface device 808 to communicate over the network 820. The computer system 800 also may include a video display unit 810 (e.g., a liquid crystal display (LCD) or a cathode ray tube (CRT)), an alphanumeric input device 812 (e.g., a keyboard), a cursor control device 814 (e.g., a mouse), a graphics processing unit 822, a signal generation device 816 (e.g., a speaker), graphics processing unit 822, video processing unit 828, and audio processing unit 832.

The data storage device 818 may include a machine-readable storage medium 824 (also known as a non-transitory computer-readable medium) on which is stored one or more sets of instructions 826 or software embodying any one or more of the methodologies or functions described herein. The instructions 826 may also reside, completely or at least partially, within the main memory 804 and/or within the processing device 802 during execution thereof by the computer system 800, the main memory 804 and the processing device 802 also constituting machine-readable storage media.

In some implementations, the instructions 826 include instructions to implement functionality corresponding to the present disclosure. While the machine-readable storage medium 824 is shown in an example implementation to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine and the processing device 802 to perform any one or more of the methodologies of the present disclosure. The term “machine-readable storage medium” shall accordingly be taken to include, but not be limited to, solid-state memories, optical media, and magnetic media.

In some aspects of the present disclosure, the processing device 802 may include a memory compiler 827. The memory compiler 827 may generate a representation of a memory in accordance with certain aspects of the present disclosure.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm may be a sequence of operations leading to a desired result. The operations are those requiring physical manipulations of physical quantities. Such quantities may take the form of electrical or magnetic signals capable of being stored, combined, compared, and otherwise manipulated. Such signals may be referred to as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the present disclosure, it is appreciated that throughout the description, certain terms refer to the action and processes of a computer system, or similar electronic computing device, that manipulates and transforms data represented as physical (electronic) quantities within the computer system's registers and memories into other data similarly represented as physical quantities within the computer system memories or registers or other such information storage devices.

The present disclosure also relates to an apparatus for performing the operations herein. This apparatus may be specially constructed for the intended purposes, or it may include a computer selectively activated or reconfigured by a computer program stored in the computer. Such a computer program may be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various other systems may be used with programs in accordance with the teachings herein, or it may prove convenient to construct a more specialized apparatus to perform the method. In addition, the present disclosure is not described with reference to any particular programming language. It will be appreciated that a variety of programming languages may be used to implement the teachings of the disclosure as described herein.

The present disclosure may be provided as a computer program product, or software, that may include a machine-readable medium having stored thereon instructions, which may be used to program a computer system (or other electronic devices) to perform a process according to the present disclosure. A machine-readable medium includes any mechanism for storing information in a form readable by a machine (e.g., a computer). For example, a machine-readable (e.g., computer-readable) medium includes a machine (e.g., a computer) readable storage medium such as a read only memory (“ROM”), random access memory (“RAM”), magnetic disk storage media, optical storage media, flash memory devices, etc.

In the foregoing disclosure, implementations of the disclosure have been described with reference to specific example implementations thereof. It will be evident that various modifications may be made thereto without departing from the broader spirit and scope of implementations of the disclosure as set forth in the following claims. Where the disclosure refers to some elements in the singular tense, more than one element can be depicted in the figures and like elements are labeled with like numerals. The disclosure and drawings are, accordingly, to be regarded in an illustrative sense rather than a restrictive sense.

What is claimed is:

1. A method for memory processing, comprising:
determining, via one or more processors and for each of different quantities of columns per section of a memory, a read signal indicating a change in a bitline signal during a read window based on at least one calculated slope of the bitline signal during the read window, wherein the read signal being determined for each of the different quantities of the columns per section of the memory yields a plurality of read signals;
determining a difference between at least two of the plurality of read signals;
identifying breakpoints within the memory based on the difference between the at least two of the plurality of read signals; and
generating a representation of the memory based on the breakpoints.

2. The method of claim 1, wherein the bitline signal comprises a signal at a complementary bitline of the memory.

3. The method of claim 1, wherein generating the representation of the memory based on the breakpoints includes separately tuning different sections of the memory based on the breakpoints within the memory.

4. The method of claim 1, wherein the at least two of the plurality of read signals are for two consecutive quantities of the columns per section of the memory.

5. The method of claim 1, wherein the read window comprises a time duration from a rising edge of a wordline signal of the memory until a rising edge of a sense amplifier enable signal of the memory.

6. The method of claim 5, wherein:
the rising edge of the wordline signal comprises a time at which the wordline signal reaches 80% of a logic high voltage; and
the rising edge of the sense amplifier enable comprises a time at which the sense amplifier enable signal reaches 50% of the logic high voltage.

7. The method of claim 1, wherein the at least one calculated slope includes:
a first calculated slope of the bitline signal for a first portion of the read window; and
a second calculated slope of the bitline signal for a second portion of the read window.

8. The method of claim 7, wherein:
the first portion of the read window includes a time at which a wordline signal of the memory reaches 80% of a logic high voltage until a time at which the wordline signal reaches 98% of the logic high voltage; and
the second portion of the read window includes the time at which the wordline signal reaches 98% of the logic high voltage until a time at which a sense amplifier enable signal of the memory reaches 50% of the logic high voltage.

9. The method of claim 1, wherein the change in the bitline signal comprises a difference between a signal at a bitline of the memory and a signal at a complementary bitline of the memory.

10. The method of claim 1, wherein the at least one calculated slope is calculated based on at least one of a read current associated with a bitcell of the memory, a supply voltage for the memory, a threshold voltage of the memory, a bitline capacitance associated with the memory, a capacitance at a bitline input and output (I/O) interface for the memory, a quantity of wordlines of the memory, or a wordline voltage level target of the memory.

11. The method of claim 1, further comprising reducing a resistance or capacitance mismatch between at least two lines the memory prior to determining the plurality of read signals.

12. The method of claim 11, wherein the at least two lines includes a wordline and a sense amplifier enable line.

13. An apparatus for memory processing, comprising:
a storage device; and
one or more processors coupled to the storage device, the one or more processing being configured to:
determine, for each of different quantities of columns per section of a memory, a read signal indicating a change in a bitline signal during a read window based on at least one calculated slope of the bitline signal during the read window, wherein the read signal being determined for each of the different quantities of the columns per section of the memory yields a plurality of read signals;
determine a difference between at least two of the plurality of read signals;
identify breakpoints within the memory based on the difference between the at least two of the plurality of read signals; and
generate a representation of the memory based on the breakpoints.

14. The apparatus of claim 13, wherein the bitline signal comprises a signal at a complementary bitline of the memory.

15. The apparatus of claim 13, wherein, to generate the representation of the memory based on the breakpoints, the one or more processors are configured to separately tune different sections of the memory based on the breakpoints within the memory.

16. The apparatus of claim 13, wherein the at least two of the plurality of read signals are for two consecutive quantities of the columns per section of the memory.

17. The apparatus of claim 13, wherein the read window comprises a time duration from a rising edge of a wordline signal of the memory until a rising edge of a sense amplifier enable signal of the memory.

18. The apparatus of claim 17, wherein:
the rising edge of the wordline signal comprises a time at which the wordline signal reaches 80% of a logic high voltage; and
the rising edge of the sense amplifier enable comprises a time at which the sense amplifier enable signal reaches 50% of the logic high voltage.

19. The apparatus of claim 13, wherein the at least one calculated slope includes:
a first calculated slope of the bitline signal for a first portion of the read window; and
a second calculated slope of the bitline signal for a second portion of the read window.

20. A non-transitory computer-readable medium having instructions stored thereon, that when executed by one or more processors, cause the one or more processors to:
determine, for each of different quantities of columns per section of a memory, a read signal indicating a change in a bitline signal during a read window based on at least one calculated slope of the bitline signal during the read window, wherein the read signal being determined for each of the different quantities of the columns per section of the memory yields a plurality of read signals;
determine a difference between at least two of the plurality of read signals;
identify breakpoints within the memory based on the difference between the at least two of the plurality of read signals; and
generate a representation of the memory based on the breakpoints.
